(19) United States
(12) Patent Application Publication
(10) Pub. No.: US 2026/0050226 A1
(43) Pub. Date: Feb. 19, 2026

(54) LIGHT GENERATION DEVICE AND LITHOGRAPHY APPARATUS INCLUDING THE SAME

(71) Applicant: Samsung Electronics Co., Ltd., Suwon-si (KR)

(72) Inventors: Seungpyo HONG, Suwon-si (KR); Sunghyup KIM, Suwon-si (KR); Daegeun YOON, Suwon-si (KR); Injae LEE, Suwon-si (KR)

(73) Assignee: Samsung Electronics Co., Ltd., Suwon-si (KR)

(21) Appl. No.: 19/237,648

(22) Filed: Jun. 13, 2025

(30) Foreign Application Priority Data
Aug. 16, 2024 (KR) 10-2024-0109719

(51) Int. Cl. G03F 7/00

(52) U.S. Cl. CPC G03F 7/70916; G03F 7/70033; G03F 7/70175

(57) ABSTRACT

A light generation device includes a vessel configured to define an internal space extending in a first direction, a collector disposed adjacent to one end portion of the vessel and having an aperture at a central portion of the collector, a droplet generator configured to provide a droplet to the internal space of the vessel, a light source configured to provide a laser beam to the droplet in the vessel, and a flow guide configured to control a flow path of gas supplied to the internal space of the vessel, wherein the flow guide may include a first flow guide connected to the collector, a second flow guide provided within the aperture and spaced apart from the first flow guide, and a third flow guide provided between the first and second flow guides.

### CROSS-REFERENCE TO RELATED APPLICATION(S)

This U.S. non-provisional application claims priority under 35 USC § 119 to Korean Patent Application No. 10-2024-0109719, filed on Aug. 16, 2024, in the Korean Intellectual Property Office, the disclosure of which is herein incorporated by reference in its entirety.

### BACKGROUND

Example embodiments relate to a light generation device and a lithography apparatus including the same, and more particularly, to an extreme ultraviolet (EUV) light generation device used in a semiconductor device manufacturing process and a lithography apparatus including the same.

With the growing demand for advanced semiconductor device manufacturing processes and the limitations of current technologies, lithography techniques using extreme ultraviolet (EUV) light are emerging as a promising solution. A minimum feature size of integrated circuits formed through a lithography process is dependent on a wavelength of a light source. Accordingly, the wavelength of the light source may be shortened to process semiconductor devices more precisely. EUV light is a type of short-wavelength light (e.g., between 4 to 124 nanometers (nm)), and a common method of generating EUV light is a laser-produced plasma (LPP) technique, which involves irradiating a metal droplet, such as tin, with a laser beam. However, contaminants such as debris from metal droplets generated during a process of generating EUV light may adhere to the EUV light source and/or components within a lithography apparatus receiving the EUV light to perform a lithography process, thereby causing defects in equipment.

### SUMMARY

Example embodiments provide a light generation device having improved reliability and a lithography apparatus including the same.

According to an example embodiment, a light generation device includes a vessel configured to define an internal space, the internal space extending in a first direction; a collector adjacent to one end portion of the vessel, the collector having an aperture at a central portion of the collector; a droplet generator configured to provide a droplet to the internal space of the vessel; a light source configured to irradiate the droplet in the vessel with a laser beam and a flow guide configured to control a flow path of gas supplied to the internal space of the vessel. The flow guide may include a first flow guide connected to the collector, a second flow guide in the aperture and spaced apart from the first flow guide, and a third flow guide between the first and second flow guides.

According to an example embodiment, a lithography apparatus includes a light generation device configured to outputs extreme ultraviolet (EUV) light; a stage configured to mount a substrate; and a mask configured to reflect the EUV light output from the light generation device towards the stage. The light generation device may include a vessel configured to define an internal space, the internal space extending in a first direction; a collector adjacent to one end portion of the vessel, the collector having an aperture at a central portion of the collector; a droplet generator configured to provide a droplet to the internal space of the vessel; a light source configured to irradiate the droplet in the vessel with a laser beam; and a flow guide configured to control a flow path of gas supplied to the internal space of the vessel. The flow guide may include a first flow guide connected to the collector, a second flow guide in the aperture and spaced apart from the first flow guide, and a third flow guide between the first and second flow guides.

### BRIEF DESCRIPTION OF DRAWINGS

FIG. 1 is a schematic diagram of a light generation device according to some example embodiments.

FIG. 2A is a cross-sectional view illustrating a region denoted as A1 in FIG. 1, and

FIG. 2B is an enlarged cross-sectional view of A2 in FIG. 2A.

FIG. 3 is a plan view illustrating a region denoted as A1 in FIG. 1.

FIG. 4 is a cross-sectional view illustrating a portion of a light generation device according to some example embodiments.

FIG. 5A is a schematic diagram illustrating a flow path of a light generation device employing a flow guide according to a comparative example, and FIG. 5B is a schematic diagram illustrating a movement direction of debris generated during a light generation process when the light generation device of FIG. 5A operates.

FIG. 6A is a schematic diagram illustrating a flow path of a light generation device employing a flow guide according to at least one example embodiment, and FIG. 6B is a schematic diagram illustrating a movement direction of debris generated during a light generation process when the light generation device of FIG. 6A operates.

FIGS. 7A and 7B are diagrams illustrating flow simulation results for an internal space of a vessel in the light generation device according to the comparative example described in FIG. 5A and the at least one embodiment described in FIG. 6A, respectively.

FIGS. 8A and 8B are diagrams illustrating simulation results of a concentration of debris deposited on a surface of an optical mirror in the light generation device according to the comparative example described in FIG. 5A and the embodiment described in FIG. 6A, respectively.

FIG. 9 is a schematic diagram illustrating the configuration of a lithography device according to example embodiments.

### DETAILED DESCRIPTION

Hereinafter, example embodiments will be described with reference to the accompanying drawings. Like components are denoted by like reference numerals throughout the specification, and repeated descriptions thereof may be omitted Embodiments to be described are merely examples, and various modifications may be made from such embodiments. In the drawings, sizes of components in the drawings may be exaggerated for convenience of explanation. Additionally, when the terms “about” or “substantially” are used in this specification in connection with a numerical value and/or geometric terms, it is intended that the associated numerical value includes a manufacturing tolerance (e.g., ±10%) around the stated numerical value. Further, regardless of whether numerical values and/or geometric terms are modified as “about” or “substantially,” it will be understood that these values should be construed as including a manufacturing or operational tolerance (e.g., ±10%) around the stated numerical values and/or geometry.

Additionally, spatially relative terms, such as “above”, “below”, and/or similar directional terms are intended to encompass different orientations of the device in use or operation in addition to the orientation depicted in the figures, and that the device may be otherwise oriented (rotated 90 degrees or at other orientations) and the spatially relative terms used herein interpreted accordingly.

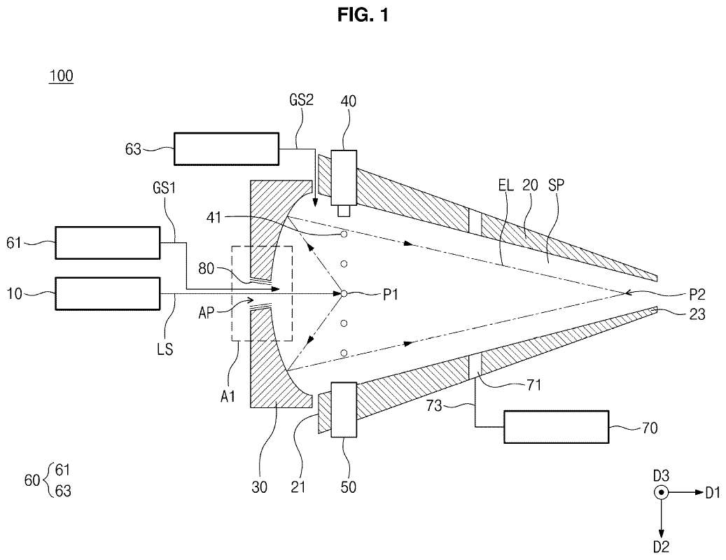

FIG. 1 is a schematic diagram of a light generation device according to some example embodiments.

Referring to FIG. 1, a light generation device 100 is configured to generate extreme ultraviolet (EUV) light. In some example embodiments, the EUV light EL may have a wavelength in the range of about 4 nm to about 124 nm. For example, the EUV light EL may have a wavelength in the range of about 4 nm to about 20 nm. In some embodiments, the EUV light EL may have a wavelength of about 13.5 nm. The EUV light EL may be used in a lithography process among other semiconductor device manufacturing processes.

The light generation device 100 may be a plasma-based light source or a synchrotron radiation light source. The plasma-based light source is configured to generate plasma and uses light emitted by the plasma. The plasma-based light source may include a laser-produced plasma (LPP) light source, a discharge-produced plasma (DPP) light source, and/or the like. In at least one example embodiment, the light generation device 100 may be an LPP light source.

The light generation device 100 may include a vessel 20, a light source 10, a collector 30, a droplet generator 40, a droplet catcher 50, a gas source 60, an exhaust portion 70, and a flow guide 80.

The vessel 20 may provide an internal space SP in which EUV light EL is generated. The vessel 20 may have a shape extending in a first direction D1. The vessel 20 may include a first end portion 21 and a second end portion 23, opposing each other. The internal space SP of the vessel 20 may extend from the first end 21 to the second end portion 23 of the vessel 20. The vessel 20 may have a tapered shape narrowed in a direction from the first end portion 21 to the second end portion 23. For example, the vessel 20 may have a conical shape narrowed in the direction from the first end portion 21 to the second end portion 23. A central axis of a cone forming the vessel 20 may be parallel to the first direction D1. Hereinafter, in the drawings, for ease of description, a direction intersecting the first direction D1 will be defined as a second direction D2 and a direction perpendicular to the first direction D1 and the second direction D2 will be defined as a third direction D3.

The first end portion 21 of the vessel 20 may be a portion, in which a laser beam LS used to generate EUV light EL is introduced, and/or a portion adjacent to the collector 30. The second end portion 23 of the vessel 20 may be a portion in which the EUV light EL generated in the vessel 20 is emitted.

The droplet generator 40 is configured to supply droplets 41 to the internal space SP of the vessel 20. The droplet generator 40 may be configured to spray the droplets 41 at regular intervals, thereby providing a steady stream of droplets 41. The droplets 41 may serve as a raw material for generating EUV light EL, and EUV light EL may be generated through an interaction between the laser beam LS, introduced into the internal space SP of the vessel 20, and the droplets 41.

The droplets 41 may include at least one element having one or more emission lines within an EUV range. For example, the droplets 41 may include at least one of tin (Sn), lithium (Li), and/or xenon (Xe). For example, the droplets 41 may include at least one of tin (Sn), a tin compound (for example, SnBr₄, SnBr₂, and/or SnH), or a tin alloy (for example, Sn—Ga, Sn—In, and/or Sn—In—Ga). The above-mentioned elements or elements may be present in the form of solid particles within the droplets 41.

The droplet generator 40 is configured to supply droplets 41 in a path intersecting the path of the laser beam LS introduced into the internal space SP of the vessel 20, for example, in the second direction D2. For example, the droplet generator 40 may spray droplets 41 toward a predetermined first position P1 in the internal space SP of the vessel 20. The first position P1 inside the vessel 20 may be a position in which a movement path of the droplets 41 intersects a propagation path of the laser beam LS, and EUV light EL may be generated through the interaction between the droplets 41 reaching the first position P1 and the laser beam LS.

The droplet catcher 50 may be disposed at a distal end of the movement path of the droplets 41, sprayed from the droplet generator 40, and is configured to collect the droplets 41 sprayed from the droplet generator 40. To this end, the droplet catcher 50 may be installed opposite to the droplet generator 40. Among the droplets 41 sprayed from the droplet generator 40, droplets 41 that do not react with the laser beam LS may be collected by the droplet catcher 50.

The light source 10 is configured to output the laser beam LS to the internal space SP of the vessel 20. The laser beam LS, provided from the light source 10, may be introduced into the vessel 20 through an aperture AP formed in the center of the collector 30 and may propagate in the first direction D1 toward the first position P1 inside the vessel 20.

In some example embodiments, the light source 10 may be configured to output a gas laser generated using a laser gain medium. For example, the light source 10 may be configured to output a carbon dioxide laser, a helium-neon laser, a nitrogen laser, an excimer laser, and/or the like.

The collector 30 may be disposed adjacent to the first end portion 21 of the vessel 20. The collector 30 may be configured to reflect the EUV light EL generated by a reaction between the laser beam LS and the droplets 41 and to collect the EUV light EL at a second position P2 adjacent to the second end portion 23 of the vessel 20.

The collector 30 may have an ellipsoidal geometry. For example, the collector 30 may have the first position P1, at which the laser beam LS and the droplets 41 meet, as a first focus and the second position P2, at which the EUV light EL reflected by the collector 30 is collected, as a second focus. The second focus may be referred to as an intermediate focus. For example, the collector 30 may selectively collect and reflect EUV light having a wavelength in the extreme ultraviolet range (for example, about 10 nm to about 14 nm) among various wavelengths of light emitted from the plasma generated from the droplets 41. In addition, the EUV light generated at the first focus may be reflected by the collector 30 toward the second focus. For example, the EUV light may be concentrated and emitted at the second focus by the collector 30.

In an example embodiment, the collector 30 may include a multilayer mirror providing an elliptical reflecting surface. The multilayer mirror may include a structure in which a plurality of layers selected from, for example, a molybdenum (Mo) layer, a silicon (Si) layer, a silicon carbide (SiC) layer, a boron carbide (B₄C) film, a molybdenum carbide (Mo₂C) layer, a silicon nitride (Si₃N₄) layer, etc. are alternately stacked. However, example embodiments are not limited thereto.

The collector 30, together with the vessel 20, may provide an internal space SP, in which EUV light EL is generated. The internal space SP defined by the vessel 20 and the collector 30 may be maintained in a vacuum state. Since the internal space SP of the vessel 20 is maintained in a vacuum state, the EUV light EL may be prevented (e.g., protected) from being absorbed by air. When the internal space SP of the vessel 20 is maintained in a vacuum state, a pressure inside the vessel 20 may be about 1.0 Torr to about 1.8 Torr.

The collector 30 may have an aperture AP penetrating through a center thereof. The laser beam LS from the light source 10 and a first gas GS1 to be described later may be supplied from an external space to the internal space SP through the aperture AP.

The gas source 60 is configured to supply gas to the internal space SP of the vessel 20. The gas source 60 may include a first gas source 61, supplying a first gas GS1 to the internal space SP, and a second gas source 63 supplying a second gas GS2 to the internal space SP. The first gas GS1 and the second gas GS2 may be used to form a predetermined flow in the internal space SP.

The first gas source 61 may supply the first gas GS1 to the internal space SP of the vessel 20 through the aperture AP of the collector 30. The first gas source 61 may supply the first gas GS1 in a direction from the first end portion 21 toward the second end portion 23 of the vessel 20, for example, in the first direction D1. The second gas source 63 may supply the second gas GS2 to the internal space SP through an inlet port provided adjacent to the first end portion 21 of the vessel 20. The second gas source 63 may supply the second gas GS2 in a direction, perpendicular to the direction from the first end portion 21 to the second end portion 23 of the vessel 20. The direction from the first end portion 21 to the second end portion 23 may be a direction toward the center of the vessel 20.

Each of the first gas GS1 and the second gas GS2 may be a gas having significantly low reactivity with the droplets 41. For example, the first gas GS1 and the second gas GS2 may include hydrogen (H₂), helium (He), argon (Ar), hydrogen bromide (HBr), or combinations thereof.

In FIG. 1, the second gas source 63 is illustrated as being supplied to the internal space SP of the vessel 20 through a single inlet port, but a plurality of inlet ports may be further provided between the first end portion 21 of the vessel 20 and the collector 30 and the second gas GS2 may be supplied to the internal space SP through the plurality of inlet ports.

In at least one example embodiment, the first gas GS1 and the second gas GS2, respectively provided from the first gas source 61 and the second gas source 63, may have the same material and/or the same composition. However, example embodiments are not limited thereto, and the first gas GS1 and the second gas GS2 may have different materials and/or different compositions.

In at least one example embodiment, the first gas GS1 and/or the second gas GS2 may be a purge gas for purging the gas in the internal space SP. The purge gas may be, for example, hydrogen and/or hydrogen radicals. The hydrogen and/or hydrogen radicals may convert tin-containing debris DBR, deposited on a surface of the internal space SP, into volatile tin compounds such as SnH₄, to easily purge the debris from the internal space SP to the outside. In some embodiments, the purge gas may include an inert gas such as helium (He) gas, argon (Ar) gas, or nitrogen (N₂) gas. However, in at least one example embodiment, the purge gas may be supplied through an additional purge gas supply unit other than the first gas source 61 and the second gas source 63. When the purge gas is additionally supplied, a nozzle may be additionally provided.

The flow guide 80 may be provided within the aperture AP to control a movement path, such as a flow path, of the first gas GS1 on the side of the aperture AP of the collector 30. Accordingly, the first gas GS1 may be supplied to the internal space SP through the aperture AP and the flow guide 80. The flow guide 80 will be described later.

The exhaust portion 70 is configured to remove gas and/or debris of the droplet 41 from the internal space SP of the vessel 20. The exhaust portion 70 may exhaust the gas in the internal space SP of the vessel 20 through an exhaust port 71 formed in the vessel 20. The exhaust port 71 formed in the vessel 20 may be disposed between the first end portion 21 and the second end portion 23 of the vessel 20. The vessel 20 may have a single exhaust port 71 or a plurality of exhaust ports 71. When the vessel 20 includes a plurality of exhaust ports 71, the plurality of exhaust ports 71 may be disposed at substantially the same height.

The exhaust portion 70 may include an exhaust pump, not illustrated, connected to the exhaust port 71 of the vessel 20 through an exhaust line 73. In addition, the exhaust portion 70 may further include a regulator adjusting the amount of gas exhausted through the exhaust line 73, a scrubber scrubbing the gas exhausted through the exhaust line 73, or the like.

In at least one example embodiment, the flow guide 80, configured to control the flow path of the first gas GS1, may be provided in the aperture AP provided at the center of the collector 30.

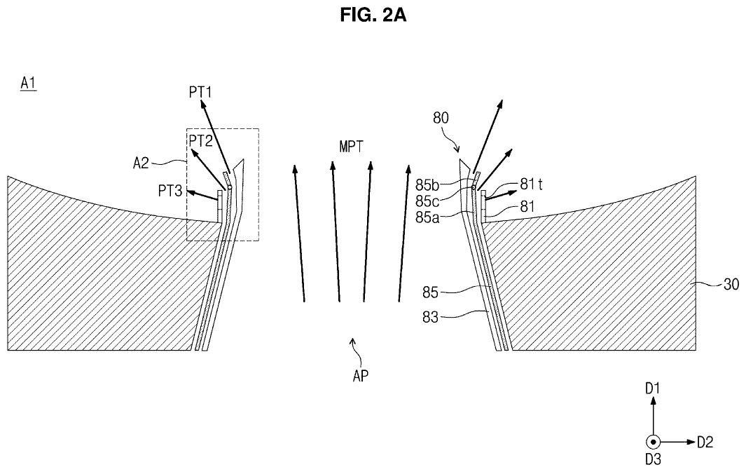

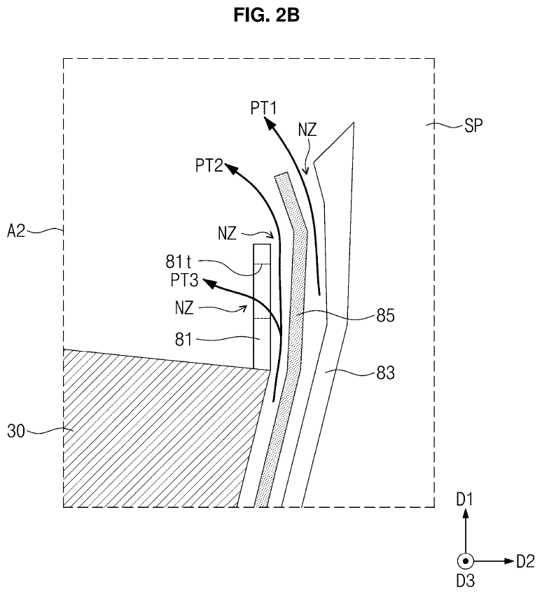

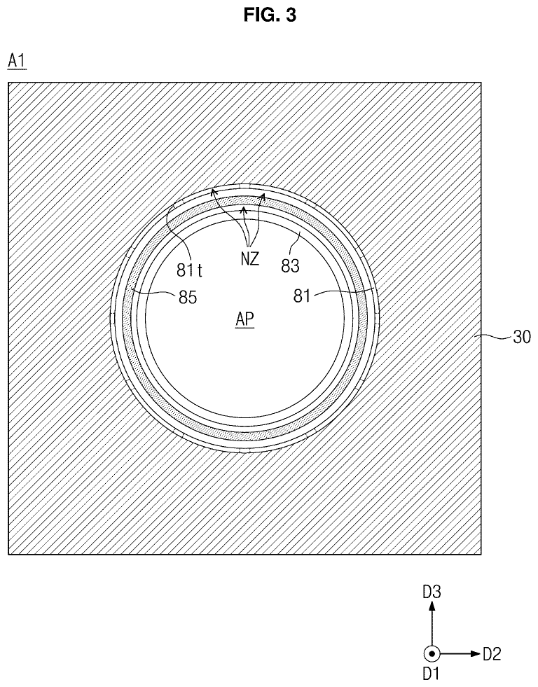

FIG. 2A is a cross-sectional view illustrating a region denoted as A1 in FIG. 1, and FIG. 2B is an enlarged cross-sectional view of A2 in FIG. 2A. FIG. 3 is a plan view illustrating a region denoted as A1 in FIG. 1.

In FIGS. 2A and 2B, for ease of description, the first direction D1 is illustrated as going upward in the drawings along a central axis of a cone provided by the vessel 20.

Referring to FIGS. 2A, 2B, and 3, the flow guide 80 is provided within the aperture AP to provide a path along which the first gas GS1 propagates. For example, the flow guide 80 may include first to third flow guides 81, 83, and 85. The first to third flow guides 81, 83, and 85 may be configured to provide a main path, along the first gas GS1 propagates, and first to third paths PT1, PT2, and PT3. This will be described in more detail below.

The flow guide 80 may be provided within the aperture AP but may be provided at a location adjacent to an end portion on the side of the aperture AP of the collector 30. The flow guide 80 may be provided along an external side of the aperture AP, for example, along the periphery of the aperture AP. The flow guide 80 may provide a path, along which the first gas GS1 flows, in the internal space SP along the periphery of the aperture AP to control the overall flow path within the internal space SP.

The flow guide 80 may have a ring shape. For example, the flow guide 80 may have a ring shape surrounding the central axis of the conical internal space SP defined by the vessel 20 and the aperture AP. In an example embodiment, a center of the ring of the flow guide 80 may match the central axis of the cone provided by the vessel 20.

In at least one example embodiment, the flow guide 80 may include a metallic material. For example, the flow guide 80 may include aluminum (Al), tungsten (W), and/or a combination thereof. Alternatively, in an example embodiment, the flow guide 80 may include ceramic or polymer. For example, the flow guide 80 may include glass, quartz, and/or Teflon.

The flow guide 80 may include a first flow guide 81 connected to the aperture AP, a second flow guide 83 spaced apart from the first flow guide 81 toward the center of the aperture AP, and a third flow guide 85 provided in the first flow guide 81 and the second flow guide 83.

Each of the first flow guide 81, the second flow guide 83, and the third flow guide 85 may have a cylindrical shape. For example, in a plan view, each of the first flow guide 81, the second flow guide 83, and the third flow guide 85 may have a ring shape. In the present embodiment, the first flow guide 81, the second flow guide 83, and the third flow guide 85 may have a concentric circle shape having the center of the aperture AP as the origin. Accordingly, the center of each of the first to third flow guides 81, 83, and 85 and the center of the aperture AP may overlap each other. In addition, in each of the first flow guide 81, the second flow guide 83, and the third flow guide 85, the ring shape may match the central axis of the conical internal space SP provided by the vessel 20.

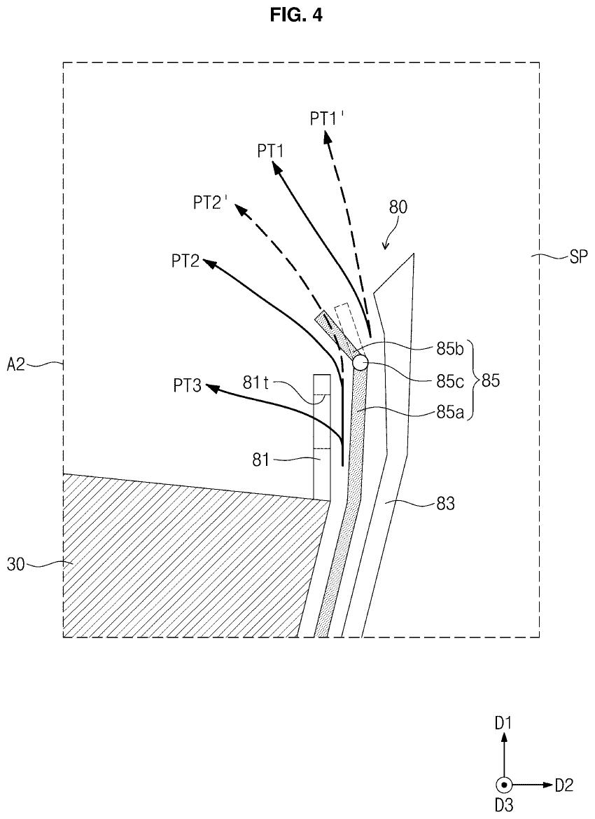

Gas may be guided by each of the first flow guide 81, the second flow guide 83, and the third flow guide 85 and be discharged to the internal space SP. An outlet, for example, nozzles NZ through which the gas is discharged may be provided in various shapes. For example, each of the nozzles NZ may be provided as a ring-shaped slit having concentric circles as illustrated in FIG. 4. The slit may be provided in plurality. However, the nozzle NZ is not limited thereto, and, for example, the nozzle NZ may be provided in the form of a plurality of holes, rather than a slit.

The first flow guide 81 may be provided at the end portion on the side of the aperture AP of the collector 30. The first flow guide 81 may be provided in a ring shape on an upper surface of the collector 30 (e.g., a surface that is in contact with the internal space SP). The location of the first flow guide 81 is not limited thereto, and the first flow guide 81 may be provided on an internal wall of the aperture AP of the collector 30.

The first flow guide 81 may protrude from the upper surface and/or from the internal wall of the collector 30 toward the internal space SP. The first flow guide 81 may have a side through-hole 81t penetrating through the protruding portion. The side through-hole 81t may be provided to penetrate through an internal surface and an external surface of the first flow guide 81.

In at least one example embodiment, the side through-hole 81t may be formed as a slit elongated in a circumferential direction of the first flow guide 81. However, example embodiments are not limited thereto, and the side through-hole 81t may have, for example, a cylindrical pipe shape. A center of each side through-hole 81t may be oriented toward a central axis of a conical internal space SP defined by the vessel 20. A plurality of side through-holes 81t may be provided in the circumferential direction of the first flow guide 81. The shape, orientation, and/or position of the side through-hole 81t may be configured such that the first gas GS1 may move radially outward from the central axis of the cone.

The second flow guide 83 may be provided in a cylindrical ring shape at a location spaced apart from the first flow guide 81 and the internal wall of the collector 30. The first flow guide 81 may be spaced apart from the internal wall of the collector 30 by a predetermined distance in a direction, such that at least a portion of the first flow guide 81 is substantially parallel to the internal wall of the collector 30. The end portion of the second flow guide 83 (e.g., a portion inside of the internal space SP) may have a shape bent at a predetermined angle from a direction, parallel to the internal wall of the collector 30. For example, the end portion of the second flow guide 83 may be bent at the predetermined angle when viewed in cross section. For example, the end portion of the second flow guide 83 may have a shape inclined at a predetermined angle in a direction away from the center of the collector 30. In at one example embodiment, the second flow guide 83 may be bent a plurality of times when viewed in cross-section.

The third flow guide 85 may be provided in a cylindrical ring shape between the first flow guide 81 and the second flow guide 83. The third flow guide 85 may have an inclined shape at an end portion, which is in contact with the internal space SP, to change the flow path of the first gas GS1. For example, an end portion of the third flow guide 85 (e.g., a portion inside the internal space SP may have a shape inclined at a predetermined angle from a direction, parallel to the internal wall of the collector 30. For example, the end portion of the third flow guide 85 may be bent at the predetermined angle when viewed in cross-section. The end portion of the third flow guide 85 may have a shape inclined at a predetermined angle in a direction away from the center of the collector 30. The inclined angle of the third flow guide 85 may be different from the inclined angle of the second flow guide 83. For example, the inclined angle of the third flow guide 85 may be larger than the inclined angle of the second flow guide 83. In at least one example embodiment, the third flow guide 85 may be bent a plurality of times when viewed in cross-section. In at least some embodiments, the position of the first flow guide 81, the second flow guide 83, and/or the third flow guide 85 may be maintained mechanically, electromagnetically, through a frictional force, etc. For example, in at least some embodiments, the flow guide 80 may be configured to be held in place using, e.g., a gasket, a clip, a binding screw post, a weld, an adhesive, a bolt, etc.

In at least one example embodiment, the inclined angles of the second flow guide 83 and the third flow guide 85 may have various values and may be the same or different from each other. For example, the inclined angles of the second flow guide 83 and the third flow guide 85 may have a value of about 0° to about 180° with respect to the first direction D1. For example, the inclined angles of the second flow guide 83 and the third flow guide 85 may have a value of about 0° to about 90°, or about 0° to about 45°, or about 0° to about 30° with respect to the first direction D1.

The main path, the first flow guide 81, the second flow guide 83, and the third flow guide 85 may have various adjusted inclined angles in consideration of the movement path of the first gas GS1 and the second gas GS2 in the internal space SP. As described above, the flow guide 80 having the adjusted inclined angle may inject the first gas GS1 in a direction inclined at a predetermined angle outward from a radial direction relative to a reference direction.

According to at least one example embodiment, the third flow guide 85 may be provided between the first flow guide 81 and the second flow guide 83, allowing flow directions of the first and second gases GS1 and GS2, for example, a flow direction of the first gas GS1 to be controlled more easily.

With the flow guide 80 having the above-described structure provided within the aperture AP, the first gas GS1 passing through the aperture AP may move along a plurality of movement paths, with a flow direction thereof being controlled. For example, the path through which the first gas GS1 moves may include a main path MPT, a first path PT1, a second path PT2, and a third path PT3.

The main path MPT may be a path through which the first gas GS1 propagates from the outside to the internal space SP through the center of the aperture AP.

The first path PT1 may be a path through which the first gas GS1 propagates from the outside to the internal space SP through a space defined between the second flow guide 83 and the first flow guide 81. The second path PT2 may be a path through which the first gas GS1 propagates from the outside to the internal space SP through a space defined between the first flow guide 81 and the third flow guide 85. The third path PT3 may be a path through which the first gas GS1 propagates from the outside to the internal space SP through a space defined between the first flow guide 81 and the third flow guide 85, but propagates to the internal space SP through the side through-hole 81t of the first flow guide 81.

In FIGS. 2A and 2B, for ease of description, the first gas GS1 discharged to the internal space SP through the main path, the first path PT1, the second path PT2, and the third path PT3 is illustrated in the form of arrows.

As illustrated in FIGS. 2A and 2B, in the light generation device 100 including the flow guide 80 according to at least one example embodiment, the first gas GS1 may mainly move in an upward direction (a direction from the first end portion 21 to the second end portion 23 along the central axis of the cone provided by the vessel 20, in the drawings).

Additionally, the first to third paths PT1, PT2, and PT3 may form different paths by the first to third flow guides 81, 83, and 85. In some embodiments, a portion of the first to third paths PT1, PT2, and PT3 may be shared. For example, the second path PT2 and the third path PT3 may share a portion of the path between the first flow guide 81 and the third flow guide 85. In the same manner, a portion of the first path PT1 and the third path PT3 or a portion of the first path PT1 and the second path PT2 may be shared. The first gas GS1 and/or the second gas GS2 provided from the first gas source 61 and/or the second gas source 63 may move through the shared path and then be branched into each path and provided to the final discharge port.

In at least one example embodiment, the flow guide 80 may include an angle-adjustable structure configured to change the movement path of the first gas GS1 to efficiently control the movement path of the first gas GS1.

FIG. 4 is a cross-sectional view illustrating a portion of the light generation device 100 according to at least one example embodiment, and illustrates a partially enlarged version of the flow guide 80.

Referring to FIG. 4, the flow guide 80 may include a first flow guide 81, a second flow guide 83, and a third flow guide 85, and the third flow guide 85 may include an angle-adjustable structure at an end portion that is in contact with the internal space SP. The angle-adjustable structure may include a structure configured to allow an angle to be adjusted, for example, a hinge, and an angle of the structures on opposite sides of the hinge may be changed through the hinge.

In at least one example embodiment, the third flow guide 85 may include a flow guide body 85a, an extension 85b provided at an end portion of the flow guide body 85a, and an angle-adjustable hinge 85c provided between the flow guide body 85a and the extension 85b to adjust an angle between the flow guide body 85a and the extension 85b. In the present embodiment, the angle-adjustable hinge 85c has been described an example of a component adjusting the angle between the flow guide body 85a and the extension 85b. However, example embodiments are not limited thereto, and other components may be used as long as they may adjust the angle between the flow guide body 85a and the extension 85b.

In the present embodiment, the angle between the extension 85b and the flow guide body 85a may be changed with the angle-adjustable hinge 85c interposed therebetween. In FIG. 4, solid lines indicate a case in which the extension 85b is provided at a first angle with respect to the flow guide body 85a, and dashed lines a case in which the extension 85b is changed to an angle different from the first angle, for example, a second angle.

When the angle between the extension 85b and the flow guide body 85a is changed, a flow direction of the first gas GS1 in a portion adjacent to the third flow guide 85 may be changed. For example, among the movement paths of the first gas GS1, the first path PT1 may be changed to a first changed path PT1′ with a change in angle of the extension 85b. Among the movement paths of the first gas GS1, the second path PT2 may be changed to a second changed path PT2′ with the change in angle of the extension 85b. In at least one example embodiment, the angle between the extension 85b and the flow guide body 85a may be controlled based on the flow rate of the first gas GS1. For example, the second path PT2 may be changed to a second changed path PT2′ by reducing the flow rate of the gate GS1 in the second path PT2. Alternatively, the angle between the extension 85b and the flow guide body 85a may be mechanically controlled using, e.g., an actuator, motor, and/or a piston (not illustrated) to adjust the position of the extension 85b.

In at least one example embodiment, the flow guide body 85a may be provided in a ring shape, and the extension 85b may be provided in plurality. This is because, even when extensions 85b provided in a ring shape are connected by the angle-adjustable hinge 85c, it may still be difficult to adjust an angle. The plurality of extensions 85b may be connected to the ring-shaped flow guide body 85a with the corresponding angle-adjustable hinges 85c interposed therebetween. Adjacent end portions of adjacent extensions 85b, among the plurality of extensions 85b, may overlap each other. An overlapping area of the overlapping end portions may vary depending on an inclined angle of the extension 85b.

The angle of the extension 85b with respect to the flow guide body 85a may be variously changed. For example, the angle of the extension 85b with respect to the flow guide body 85a may have a value of about 0° to about 180° with respect to the first direction D1. Alternatively, the angle of the extension 85b with respect to the flow guide body 85a may have a value of about 0° to about 90°, or about 0° to about 45°, or about 0° to about 30° with respect to the first direction D1.

In at least one example embodiment, while only the third flow guide 85 have been described as having an angle-adjustable structure, example embodiments are not limited thereto. According to another embodiment, the first flow guide 81 and/or the second flow guide 83 may also have an angle-adjustable structure.

The light generation device 100 having the above-described configuration may generate a laser beam LS from the light source 10. The laser beam LS may propagate to the internal space SP through the aperture AP, and may be irradiated to droplets 41 in the internal space SP to generate EUV light. When the laser beam LS is irradiated to the droplets 41, EUV light EL may be generated with an explosion, and debris including droplets 41 and solid components in the droplets 41 may be generated in the internal space SP. The debris may be discharged to the outside through the exhaust portion 70.

However, a difference between the explosion location and the location of the exhaust portion 70 may cause a surface of the internal space SP to be contaminated by the debris. According to example embodiments, the flow of the gas introduced into the interior may be controlled using the flow guide 80 to prevent (or reduce the potential for) the debris, generated at the explosion location, from being deposited on the surface of the internal space SP, for example, a surface of a condensing lens. For example, the degree of bending of the extension 85b of the third flow guide 85 is variously adjusted, allowing for various changes to the movement path of the first gas GS1.

In FIGS. 2A, 2B, and 4, only the flow path in a portion adjacent to the collector 30 and the flow guide 80 is illustrated, but the movement paths of the first gas GS1 may be minutely controlled using the first to third flow guides 81, 83, and 85 to control the overall gas flow direction in the internal space SP as well as in the space adjacent to the collector 30 and the flow guide 80.

According to at least one example embodiment, the overall flow of the first and second gases GS1 and GS2 in the internal space SP may be changed to be different only by adding the third flow guide 85, compared to the comparative example. By controlling the overall flow direction, the contamination of internal components caused by debris DBR generated during light generation, such as contaminants stacked on the internal surface of the light generation device 100, for example, on the collector 30, may be significantly reduced. This will be described in detail below.

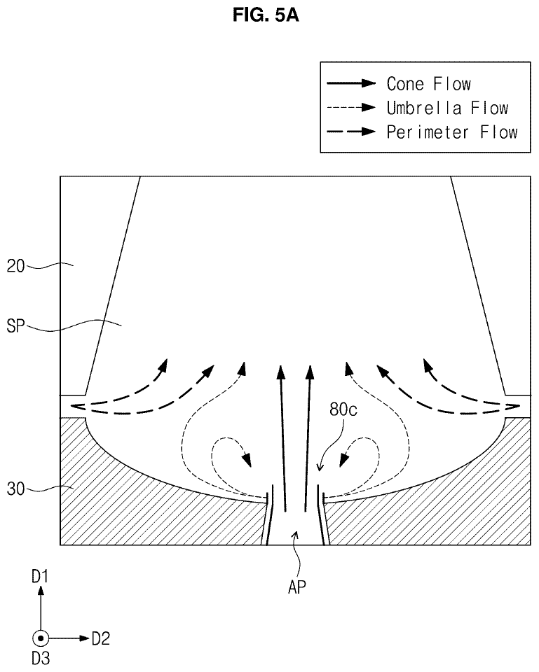

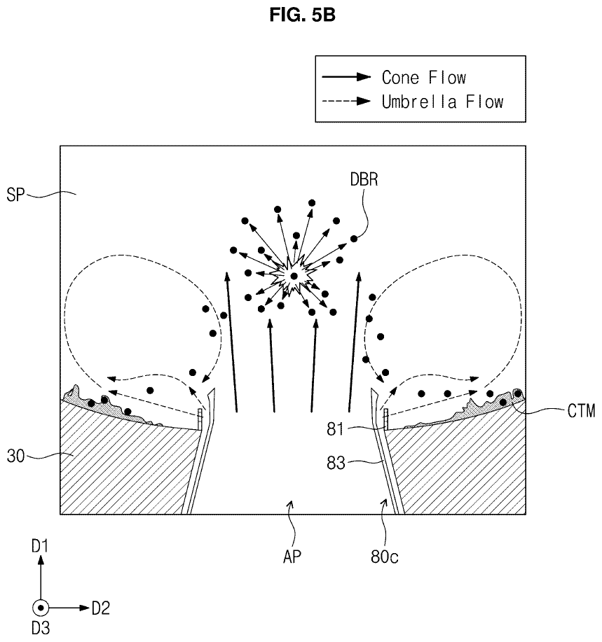

FIG. 5A is a schematic diagram illustrating a flow path of a light generation device employing a flow guide 80 according to a comparative example, different from the flow guide according to an example embodiment, and FIG. 5B is a schematic diagram illustrating a movement direction of debris DBR generated during a light generation process when the light generation device of FIG. 5A operates.

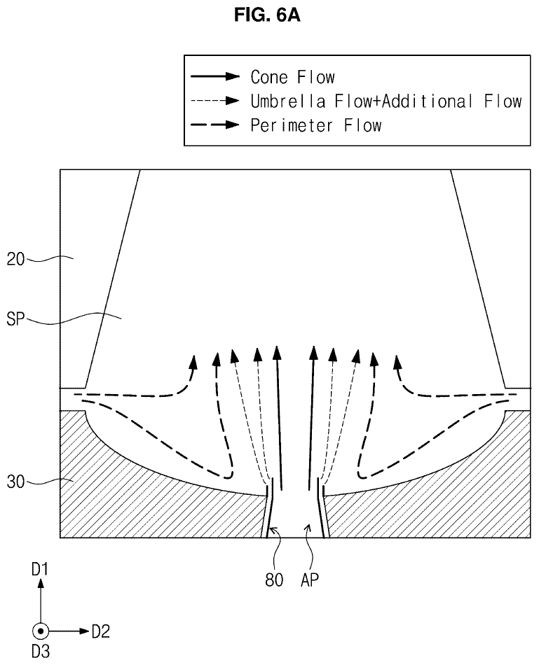

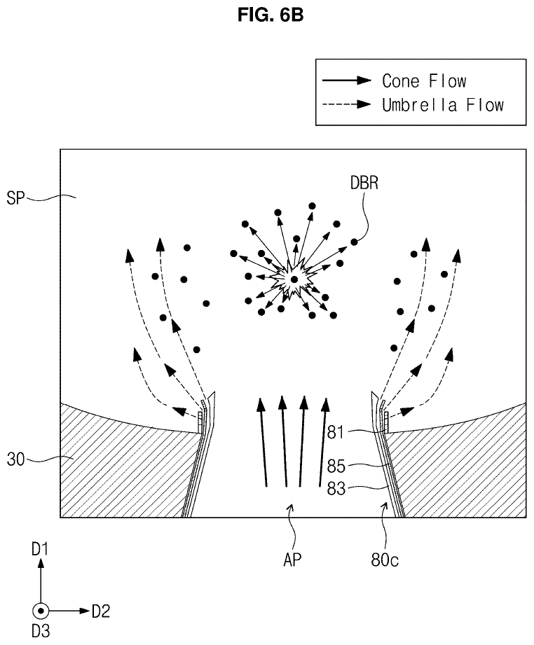

FIG. 6A is a schematic diagram illustrating a flow path of a light generation device employing a flow guide 80 according to at least one example embodiment, and FIG. 6B is a schematic diagram illustrating a movement direction of debris DBR generated during a light generation process when the light generation device of FIG. 6A operates.

Referring to FIGS. 5A and 5B, the flow guide 80 according to the comparative example may include only the first flow guide 81 and the second flow guide 83, unlike the flow guide according to the at least one example embodiment.

When a light generation device includes only the first flow guide 81 and the second flow guide 83 as in the comparative example, the gas may flow in various other directions besides an upward direction (the first direction D1) in which the exhaust portion 70 is formed.

For example, gas moving from the outside to the internal space SP through the center of the aperture AP may flow upward along the main path, following the center of the cone. In the drawing, such a gas flow is indicated as a cone flow. The gas moving from the outside to the internal space SP through the first flow guide 81 and the second flow guide 83 may flow from the inside to the outside along the surface of the collector 30. The gas may also move from an edge of the collector 30 to the inside of the collector 30. In the drawing, such a flow of gas moving from the edge to the inside of the collector 30 is indicated as a perimeter flow. The gas moving from the inside to the outside along the surface of the collector 30 may move upwardly of the collector 30 after converging with the gas moving from the edge to the inside of the collector 30. However, a portion of the converged gas may recirculate due to an interaction of gas flows having different directions. The recirculated gas may exhibit a flow returning to the upper side of the flow guide 80 and the collector 30. In the drawing, such a flow of recirculated gas is indicated as an umbrella flow.

During a light generation operation, debris DBR of the droplet 41 may be generated when the laser beam LS irradiates the droplet 41. The debris DBR of the droplet 41 may be various solid materials contained in the droplet 41, such as tin debris. The debris DBR of the droplet 41 may move toward the collector 30 along with the umbrella flow, but may be ultimately deposited on the surface of the collector 30. The debris DBR of the droplet 41 deposited on the surface of the collector 30 may function as contaminants CTM.

The contaminants CTM may significantly decrease reflectivity of the internal surface of the collector 30. The decrease in the reflectivity of the collector 30 may lead to a decrease in the conversion efficiency of extreme ultraviolet light. In addition, the contaminants CTM may fall off from the surface of the collector 30 and function as foreign objects. The foreign objects may be discharged to the outside through the second end portion 23 of the vessel 20. When the foreign objects are discharged to the outside through the second end portion 23 of the vessel 20, they may adhere to other components of the lithography apparatus, disposed at the rear end of the light generation device, to cause a facility defect. For example, when the foreign objects adhere to a mask, reliability of a lithography process may be significantly reduced due to a mask defect.

Referring to FIGS. 6A and 6B, the flow guide 80 according to an example embodiment includes the first flow guide 81 to the third flow guide 85, allowing gas to flow in an upward direction in which the exhaust portion 70 is formed. For example, according to an example embodiment, the gas may flow overall in an upward direction (a first direction D1) by the first to third flow guides 81, 83, and 85.

For example, the gas moving from the outside to the internal space SP through the center of the aperture AP may exhibit a cone flow, moving upward along the center of the cone within the main path. The gas moving from the edge of the collector 30 to the inside of the collector 30 may exhibit a perimeter flow. The gas moving from the outside to the internal space SP through the first flow guide 81 to the third flow guide 85 may converge with the gas moving from the edge of the collector 30 to the inside of the collector 30 and flow overall in the upward direction (the first direction D1). The converged flow is due to the sum of the umbrella flow and the additional flow generated by the addition of the third flow guide 85.

According to at least one example embodiment, even when there are insufficiently removed debris DBR to the side of the exhaust portion 70 by the cone flow, the sum of the umbrella flow and the additional flow may maintain the overall flow in the upward direction to fundamentally preventing (and/or reducing the amount of) the debris DBR from moving toward the collector 30. The sum of the umbrella flow and the additional flow may prevent and/or substantially reduce recirculation of the gas. Thus, according to at least one example embodiment, the movement of the debris DBR to the surface of the internal space SP, for example, the surface of the collector 30 may be reduced or prevented. The movement of the debris DBR towards the surface of the collector 30 is prevented and/or mitigated to significantly reduce deposition of the contaminants CTM of the collector 30. As a result, light collection efficiency of the collector 30 and conversion efficiency of EUV light EL may be improved. Additionally, as a result, an operational lifetime of the collector 30 may be improved.

Furthermore, the light generation device according to at least one example embodiment may employ an angle-adjustable structure to adjust the additional flow direction. The additional flow direction may be set to be different depending on flow dynamics such as a flow rate of the cone flow or a flow rate in the perimeter flow. For example, the additional flow direction may vary depending on various supply conditions of actually supplied gases, such as the first gas and/or the second gas, to the internal space SP. Accordingly, the contamination of the internal space SP, for example, the collector 30, may be significantly reduced based on the setting of the additional flow direction. As a result, significantly reducing the contamination of the collector 30 may improve the reliability of a lithography process using the lithography apparatus.

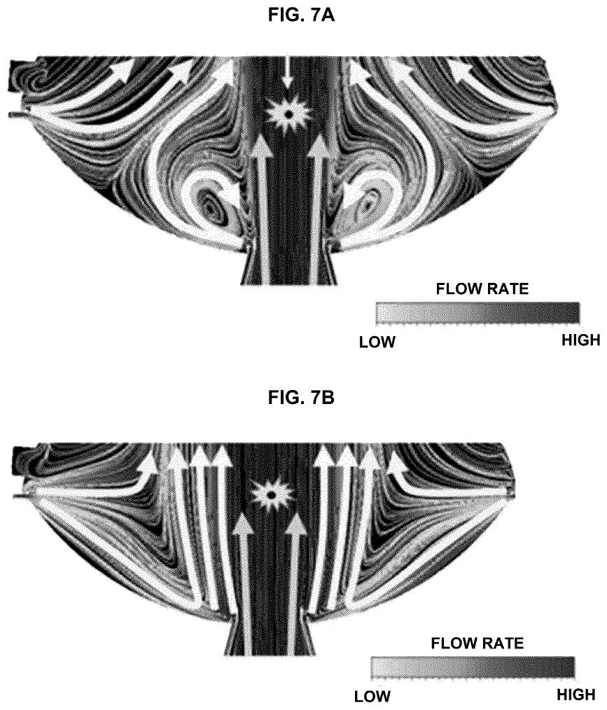

FIGS. 7A and 7B are diagrams illustrating flow simulation results for an internal space of a vessel in the light generation device according to the comparative example described in FIG. 5A and the embodiment described in FIG. 6A, respectively. Simulations were performed under the same conditions except for a flow guide in each of the light generation devices of FIGS. 7A and 7B.

Referring to FIG. 7A, it can be seen that a gas flow as illustrated in FIG. 5A is observed in the light generation device according to a comparative example. Referring to FIG. 7B, it can be seen that a flow as illustrated in FIG. 6A is observed in the light generation device according to at least one example embodiment.

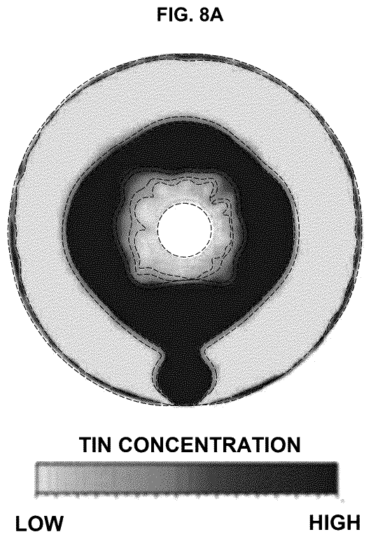

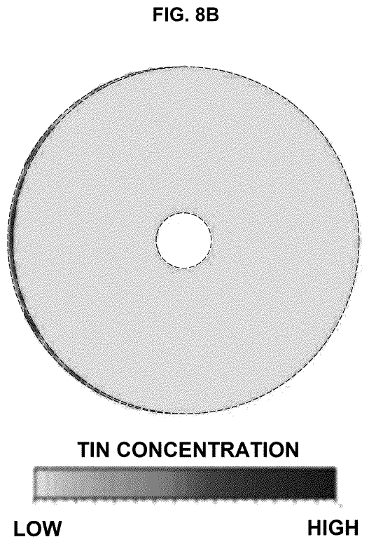

FIGS. 8A and 8B are diagrams illustrating simulation results of a concentration of debris deposited on a surface of an optical mirror in the light generation device according to the comparative example described in FIG. 5A and the at least one embodiment described in FIG. 6A, respectively. Simulations were performed under the same conditions, except for a flow guide in each of the light generation devices of FIGS. 8A and 8B, and were performed in an example in which debris was tin debris.

Referring to FIG. 8A, it can be seen that in the light generation device according to the comparative example, debris is deposited at a higher concentration on the inside rather than on the outside of an optical mirror. For example, it can be seen that the debris is deposited at a high concentration on a surface of the optical mirror corresponding to a location at which an umbrella flow is formed in the simulation of FIG. 8A. Referring to FIG. 8B, it can be seen that in the light generation device according to an example embodiment, almost no debris was deposited overall, regardless of a location of the optical mirror.

As shown in the result of the simulation, when the amount of debris deposited on the optical mirror in the light generation device according to the comparative example is 100%, the amount of debris deposited on the optical mirror in the light generation device according to an example embodiment is only 5.2%, representing a 94.8% decrease.

The light generation device according to some example embodiments may be used in various apparatuses requiring EUV light. In a semiconductor device manufacturing process, a lithography process using EUV light may be used for fine processing on a scale of several nanometers.

The light generation device according to an example embodiment may be employed in, for example, the lithography apparatus 200 used in a semiconductor device manufacturing process.

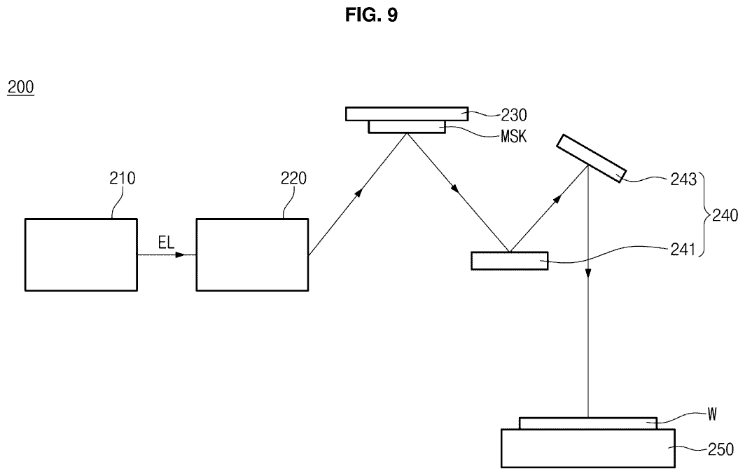

FIG. 9 is a schematic diagram illustrating the configuration of a lithography apparatus 200 according to example embodiments.

Referring to FIG. 9 together with FIG. 1, the lithography apparatus 200 may include a light generation device 210, an illumination optical system 220, a mask holder 230, a projection optical system 240, and a stage 250.

The light generation device 210 provided in the lithography apparatus 200 is the above-described extreme ultraviolet (EUV) light generation device, and is configured to output EUV light EL. The lithography apparatus 200 may be configured to perform a lithography process using the EUV light EL. The light generation device 210 may correspond to a light generation device including the above-described flow guide.

The illumination optical system 220 may include a plurality of mirrors and may be configured to transmit the EUV light EL (output from the light generation device 100) to a mask MSK. For example, the EUV light EL from the light generation device 100 may be incident on a mask MSK disposed on a mask holder 230 through reflection by the mirrors in the illumination optical system 220. The illumination optical system 220 may be configured to focus, align, and/or direct the EUV light EL towards the mask holder 230.

The mask MSK may be a reflective mask MSK having a reflective region and a non-reflective and/or intermediate reflective region. The mask MSK may include a reflective multilayer structure for reflecting the EUV light EL on a substrate W formed of a low thermal expansion coefficient material (LTEM) such as quartz, and an absorption layer pattern formed on the reflective multilayer structure. The reflective multilayer structure may include a structure in which, for example, a molybdenum (Mo) layer and silicon (Si) layer are alternately stacked in tens of layers or more. The absorption layer may be formed of, for example, TaN, TaNO, TaBO, Ni, Au, Ag, C, Te, Pt, Pd, or Cr. However, the materials of the reflective multilayer structure and the absorption layer are not limited to the above-mentioned materials. A portion of the absorption layer may correspond to the above-mentioned non-reflective and/or intermediate reflective region.

The mask MSK may reflect the EUV light EL, incident through the illumination optical system 220, such that the EUV light EL is incident on the projection optical system 240. For example, the mask MSK may structuralize light, incident from the illumination optical system 220, as projection light based on the shape of a pattern including the reflective multilayer structure and the absorption layer on a substrate W, and may inject the incident projection light into the projection optical system 240. The projection light may be structuralized through at least a second diffraction order based on a pattern on the EUV mask MSK. Such projection light may be incident on the projection optical system 240 while retaining information on the pattern shape of the EUV mask MSK, and may pass through the projection optical system 240 to generate an image corresponding to the pattern of the EUV mask MSK on the substrate W. The substrate W may be a substrate including a semiconductor material such as, for example, a wafer.

The stage 250 may be configured to move in a direction parallel to the main surface of the stage 250 while holding the substrate W, and may also move in a direction perpendicular to the main surface of the stage 250.

The projection optical system 240 may include a plurality of mirrors 241 and 243. In FIG. 2, only two mirrors 241 and 243 are illustrated in the projection optical system 240 for brevity of the drawing, but the projection optical system 240 may include additional mirrors. For example, the projection optical system 240 may typically include 4 to 8 mirrors.

As set forth above, example embodiments provide a light generation device having a structure in which debris, generated during a light generation process, are not accumulated within the light generation device. According to an example embodiment, a lithography apparatus having improved reliability may be provided by employing the light generation device.

While example embodiments have been shown and described above, it will be apparent to those skilled in the art that modifications and variations could be made without departing from the scope of the present inventive concept as defined by the appended claims.

What is claimed is:

1. A light generation device comprising:
a vessel configured to define an internal space, the internal space extending in a first direction;
a collector adjacent to one end portion of the vessel, the collector having an aperture at a central portion of the collector;
a droplet generator configured to provide a droplet to the internal space of the vessel;
a light source configured to irradiate the droplet in the vessel with a laser beam; and
a flow guide configured to control a flow path of gas supplied to the internal space of the vessel, the flow guide comprising
a first flow guide connected to the collector,
a second flow guide in the aperture and spaced apart from the first flow guide, and
a third flow guide between the first and second flow guides.

2. The light generation device of claim 1, wherein the third flow guide has an angle-adjustable structure at an end portion of the third flow guide, the end portion extending from a remainder of the third flow guide in the first direction.

3. The light generation device of claim 2, wherein the angle-adjustable structure comprises:
a flow guide body,
an extension connected to an end portion of the flow guide body, and
an angle-adjustable hinge connecting the flow guide body and the extension.

4. The light generation device of claim 3, wherein the extension is inclined with respect to the first direction.

5. The light generation device of claim 3, wherein the extension has an inclined shape in a direction away from a center of the collector with respect to the flow guide body.

6. The light generation device of claim 3, wherein the extension is included in a plurality of extensions.

7. The light generation device of claim 1, wherein each of the second and third flow guides has an end portion on a side extending towards the internal space and bent obliquely.

8. The light generation device of claim 7, wherein the second and third flow guides are each inclined at different angles with respect to the first direction.

9. The light generation device of claim 1, wherein the vessel comprises the end portion adjacent to the collector and a second end portion that oppose each other such that the internal space extends from the end portion adjacent to the collector towards the second end portion of the vessel.

10. The light generation device of claim 9, wherein the internal space has a conical shape narrowing towards the second end portion of the vessel.

11. The light generation device of claim 1, further comprising:
a gas source configured to supply gas to the internal space,
wherein the gas source comprises a first gas source configure to supply a first gas to the internal space and a second gas source configured to a second gas to the internal space.

12. The light generation device of claim 11, wherein the flow guide is configured such that a portion of the first gas is provided in the internal space through a first path between the second and third flow guides, a second path between the first and third flow guides, and a third path passing through a side through-hole in the first flow guide.

13. The light generation device of claim 12, wherein the second gas source is configured to supply the second gas to the internal space through an inlet port between the vessel and the collector.

14. The light generation device of claim 12, further comprising:
an exhaust portion in the vessel, the exhaust portion configured to exhaust gas inside the vessel through an exhaust port.

15. The light generation device of claim 1, wherein each of the first to third flow guides are comprise a ring shape.

16. The light generation device of claim 15, wherein a center of each of the first to third flow guides and the center of the aperture overlap with each other.

17. A lithography apparatus comprising:
a light generation device configured to output extreme ultraviolet (EUV) light; and
a stage configured to mount a substrate; and
a mask configured to reflect the EUV light output from the light generation device towards the stage
wherein the light generation device comprises
a vessel configured to define an internal space, the internal space extending in a first direction,
a collector adjacent to one end portion of the vessel, the collector having an aperture at a central portion of the collector,
a droplet generator configured to provide a droplet to the internal space of the vessel,
a light source configured to irradiate the droplet in the vessel with a laser beam, and
a flow guide configured to control a flow path of gas supplied to the internal space of the vessel, and
wherein the flow guide comprises a first flow guide connected to the collector, a second flow guide in the aperture and spaced apart from the first flow guide, and a third flow guide between the first and second flow guides.

18. The lithography apparatus of claim 17, wherein
the third flow guide has an angle-adjustable structure at an end portion of the third flow guide, and
the angle-adjustable structure comprises a flow guide body an extension at an end portion of the flow guide body, and an angle-adjustable hinge connecting the flow guide body and the extension.

19. The lithography apparatus of claim 17, wherein the light generation device further comprises:
a first gas source configured to supply a first gas to the internal space, and
a second gas source configured to a second gas to the internal space.

20. The lithography apparatus of claim 19, wherein the flow guide is configured such that a portion of the first gas is provided in the internal space through a first path between the second and third flow guides, a second path between the first and third flow guides, and a third path passing through a side through-hole in the first flow guide.
